(19) United States
(12) Patent Application Publication
(10) Pub. No.: US 2026/0113045 A1
(43) Pub. Date: Apr. 23, 2026

(54) FREQUENCY DIVIDER AND METHOD OF OPERATING

(71) Applicant: STMicroelectronics International N.V., Geneva (CH)

(72) Inventor: Frederic Rivoirard, Montferrat (FR)

(21) Appl. No.: 19/341,687

(22) Filed: Sep. 26, 2025

(30) Foreign Application Priority Data
Oct. 22, 2024 (FR) 2411531

(51) Int. Cl. H03L 7/18; H03K 3/356

(52) U.S. Cl. CPC H03L 7/18; H03K 3/356

(57) ABSTRACT

The present description concerns a frequency divider, comprising at least two latches and in which a pulling current of each latch is controlled by a reference current.

### CROSS-REFERENCE TO RELATED APPLICATIONS

This application claims priority to French Application No. 2411531, filed on Oct. 22, 2024, which application is hereby incorporated herein by reference.

### TECHNICAL FIELD

The present disclosure generally concerns frequency dividers and their operating methods.

### BACKGROUND

Frequency dividers are used in many radio frequency devices, for example in radio frequency receiver chains or for data transfer. In radio frequency receiver chains, for example, frequency dividers are used to bring a local oscillator operating in the GHz range closer to a crystal oscillator operating in the MHz range. Frequency dividers can also be used to generate a phase shift required for quadrature modulation.

Current frequency dividers are limited, especially as concerns the setting of the amplitude and frequency ranges in which they can operate. Their power consumption is also high.

### SUMMARY

There exists a need to provide a frequency divider having improved amplitude and frequency ranges, while limiting their power consumption.

An embodiment overcomes all or part of the disadvantages of known frequency dividers.

An embodiment provides a frequency divider, comprising at least two latches, and in which a draw current of each latch is controlled by a reference current.

An embodiment provides a method of operation of a frequency divider comprising at least two latches, the method comprising the control of a pulling current of each latch by a reference current.

According to an embodiment, the latches are in series and each latch comprises a first node, common to the two latches, for applying a first clock signal; a second node, common to both latches, for applying a second clock signal different from the first clock signal; and a first pulling transistor, having a control node coupled to the first node.

According to an embodiment, the frequency divider comprises a control loop comprising a node of application of the reference current coupled to the second node.

According to an embodiment, the control loop comprises a differential amplifier having a first input coupled to a first terminal of application of a first reference voltage via a first resistor; a second input coupled to a first conduction node of the first transistor of each of the latches, the first conduction node of the first transistor being coupled to the first terminal via a pulling resistor; and an output is coupled to a control node of the first transistor.

According to an embodiment, the output of the amplifier is coupled to the control node of the first transistor via a second resistor.

According to an embodiment, the control loop comprises at least one current mirror, coupled to the amplifier, and configured to copy the reference current.

According to an embodiment, the at least one current mirror is configured to copy the reference current and power the amplifier with the copied current.

According to an embodiment, the latches each comprise a first branch having a second and a third transistors in series between a second terminal of application of a second reference voltage and a second conduction node of the first transistor; and a second branch having a fourth and a fifth transistors in series between the second terminal and the second node; a control node of the second transistor being coupled to a junction point of the fourth and fifth transistors, and a control node of the fourth transistor being coupled to a junction point of the second and third transistors.

According to an embodiment, the latches each comprise a sixth transistor coupling the second terminal and the junction point of the second and third transistors; and a seventh transistor coupling the second terminal and the junction point of the fourth and fifth transistors; the second node being coupled to a control node of the sixth and seventh transistors.

According to an embodiment, the node of application of the reference current is coupled to the second node of each of the latches via a third resistor.

According to an embodiment: a control node of the third transistor of a first latch of the frequency divider is coupled to the junction point of the fourth and fifth transistors of a second latch of the frequency divider; and a control node for the fifth transistor of the first latch is coupled to the junction point of the second and third transistors of the second latch.

According to an embodiment, the first reference voltage is ground and the second reference voltage is VDD.

According to an embodiment, the reference current originates from a digital-to-analog converter.

An embodiment provides a radio frequency device comprising a receiver or transmitter chain comprising a frequency divider such as described hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an example of a frequency divider;

FIG. 2 shows a circuit of the frequency divider of FIG. 1;

FIG. 3 shows a frequency divider according to an embodiment;

FIG. 4 shows a circuit of the frequency divider of FIG. 3 according to an embodiments; and

FIG. 5 shows a timing diagram of the operation of the frequency divider of FIG. 3.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the text, the terms radio frequency refer to a frequency domain in the range from 1 to 120 GHz.

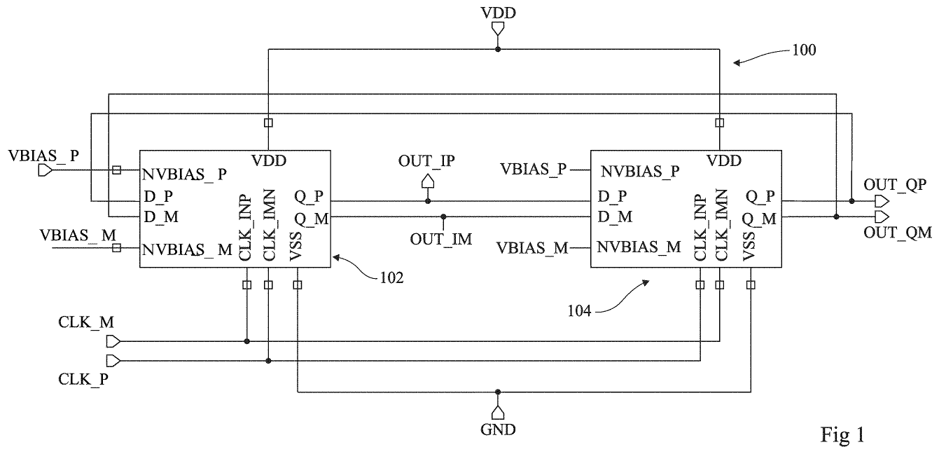

FIG. 1 shows an example of a frequency divider 100.

In the shown example, frequency divider 100 comprises two latches 102 and 104 in series. In other words, the outputs Q_P and Q_M of latch 102 are coupled, preferably connected, to the inputs D_P and D_M of latch 104. Latches are asynchronous circuits which store an information bit, that is, a memory cell, and retain its value until it is updated by new input signals.

In the shown example, latches 102 and 104 are identical or similar, to within manufacturing differences. Each of latches 102, 104 comprises inputs CLK_INP and CLK_INM configured to receive different clock signals CLK_M and respectively CLK_P, for example phase-shifted by 180°, that is, in phase opposition. These inputs are common to both latches, that is, they are respectively coupled.

In the example of FIG. 1, each latch 102, 104 is coupled to a terminal of application of a reference voltage VSS, for example, coupled to ground, and is coupled to a terminal of application of another reference voltage, for example VDD.

Each of latches 102, 104 comprises input nodes NVBIAS_M and NVBIAS_P configured to respectively receive DC bias voltages VBIAS_M and VBIAS_P. VBIAS_M and VBIAS_P are intended to be applied indirectly, via a resistor, to gates of transistor of latches 102, 104. In particular, in an example, VBIAS_M is applied to latches 102, 104 to bias the control gate of a pulling transistor of these latches.

In a way not shown in FIG. 1, each of latches 102, 104 further comprises an input configured to receive a signal BACK_GATE_TUNING for controlling the back gate of a transistor.

To obtain a frequency divider, the Q_P and Q_M outputs of latch 104 are coupled, preferably connected, respectively to the inputs D_M and D_P of latch 102.

The example of FIG. 1 allows a division by two, but a division by a higher number may be implemented by those skilled in the art by increasing the number of latches in series, for example four latches in series for the generation of signals with a frequency divided by four.

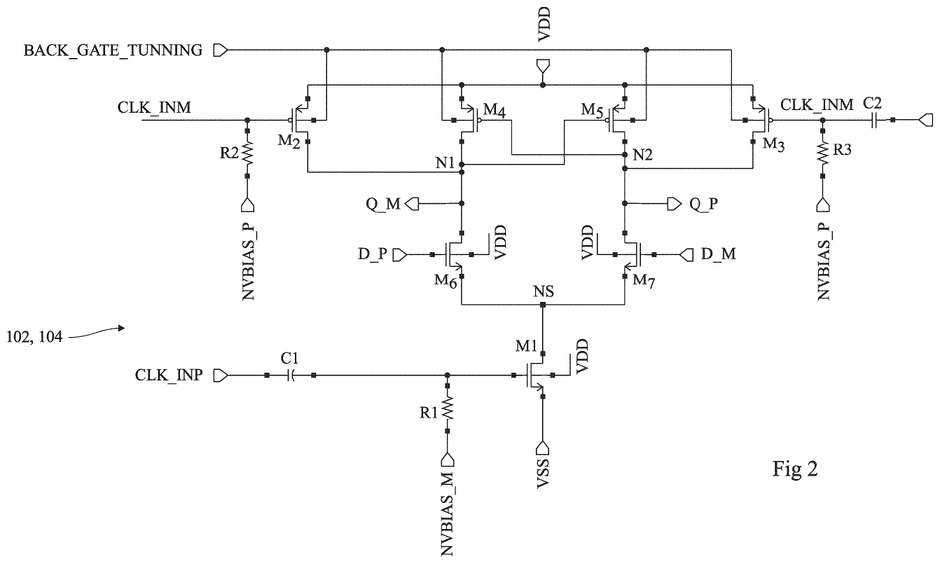

FIG. 2 shows a circuit of the frequency divider of FIG. 1. The shown example illustrates in particular an example of one of latches 102, 104.

The shown latch 102, 104 comprises a pulling transistor M1, used as a transconductor, which is for example of NMOS type, and having a main control node coupled to input node CLK_INP, for example via an optional capacitive element C1 which is used as a DC isolation.

The shown latch 102, 104 comprises a first branch having transistors M4 and M6 in series between the terminal of application of reference voltage VDD and a conduction node NS of transistor M1. In an example, transistor M4 is PMOS and transistor M6 is NMOS. The shown latch 102, 104 further comprises a second branch having transistors M5 and M7 in series between the terminal of application of reference voltage VDD and the conduction node NS of transistor M1. In an example, transistor M5 is of PMOS type and transistor M7 is of NMOS type. A main control node of transistor M4 is coupled to a junction point N2 of transistors M5 and M7, and a main control node of transistor M5 is coupled to a junction point N1 of transistors M4 and M6.

In the example of the latch 102, 104 shown in FIG. 2, a transistor M2 couples the terminal of application of reference voltage VDD to the junction point N1 of transistors M4 and M6. Further, a transistor M3 couples the terminal of application of voltage VDD and the junction point N2 of transistors M5 and M7. In an example, transistors M2 and M3 are of PMOS type.

In the shown example, node CLK_INM is coupled, preferably connected, for example via an optional isolation or filtering capacitive element C2, to a main control node of transistors M2 and M3.

Node NVBIAS_P is coupled to node CLK_INM via a resistor R2 on the side of transistor M2, and respectively R3 on the side of transistor M3. In an example, resistors R2 and R3 have the same value or are one and the same resistor.

In the shown example, node NVBIAS_M is coupled to the main control node, that is, the front gate, for example, of transistor M1, via a resistor R1.

In FIG. 2, nodes N1 and N2 are differential outputs, respectively Q_M, Q_P, of the latch, and the main control nodes of transistors M6 and M7 are differential inputs, respectively D_P, D_M, of the latch.

In an example, to form the frequency divider, the main control node of the transistor M6 of latch 102 is coupled to the junction point N2 of transistors M5, M7 of the other latch 104 of the divider. Further, the main control node of the transistor M7 of latch 102 is coupled to the junction point N1 of the transistors M4, M6 of latch 104.

In the example of FIG. 2, transistors M1, M2, M3, M4, M5, M6, and M7 are formed by using the fully depleted silicon-on-insulator (FDSOI) technology, they have a main control gate, also known as the main control node or front gate, as well as a back gate or secondary control node. In the shown example, the back gates of transistors M1, M6, and M7 are coupled to the terminal of application of voltage VDD. The back gates of transistors M2, M3, M4, and M5 are coupled to each other and are configured to receive back gate control signal BACK_GATE_TUNING.

CLK_INP and CLK_INM control both the control gate of transistor M1 and transistors M2 and M3. Transistors M6 and M7 draw the current according to inputs D_P, and D_M respectively. Transistors M4 and M5 generate a memory cell that enables division by two. Back-gate control signal BACK_GATE_TUNING modifies their threshold voltage, which has the effect of varying the drain-source resistance Rds of the transistors. As a summary, the example of latch of FIG. 2 enables to increase the frequency tuning of frequency divider 100, based on a control of a back-gate voltage of the transistors of latches 102 and 104.

The examples in FIGS. 1 and 2 however suffer from distortions due to harmonics. The power consumption is further high, or even doubled, due to the fact that the pulling current, that is, the current through transistor M1, varies according to the amplitude of the incoming radio frequency signals. The usable frequency range is limited because the back-gate control voltage is limited. Finally, these examples are limited to implementation with the FDSOI technology.

To overcome these disadvantages, the embodiments disclosed hereafter provide for a pulling current of each latch to be controlled by a reference current.

This allows an implementation in technologies which are not limited to FDSOI, such as for example the FinFet technology with fin field-effect transistors or so-called “3D” transistors. This also enables the range of the radio frequency signal to be processed to have little impact on the draw current. Eventually, this enables to obtain an amplitude and frequency tuning capability which is increased.

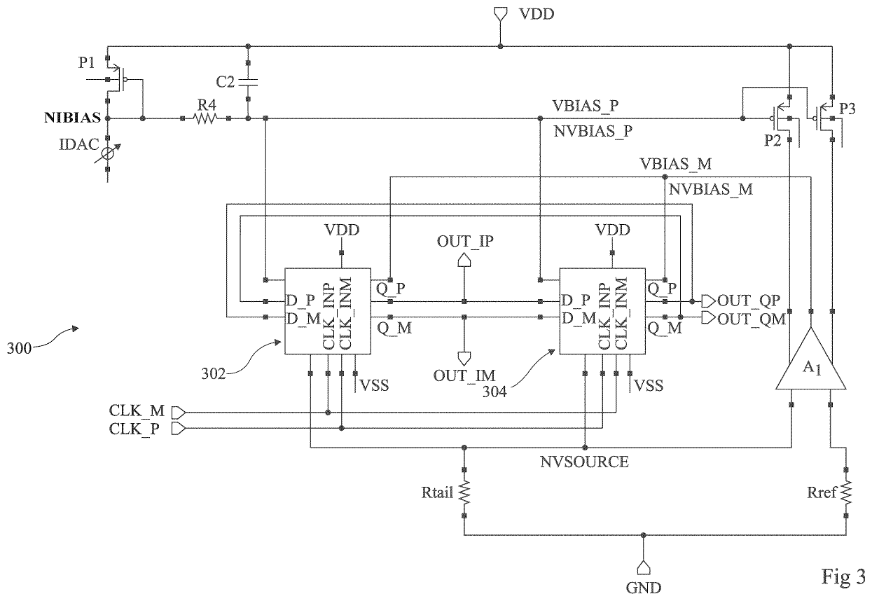

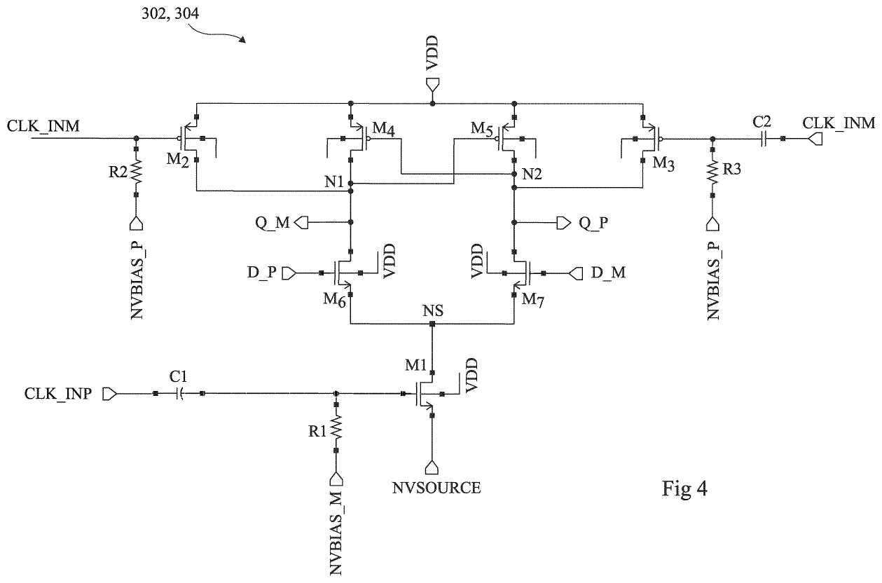

FIG. 3 shows a frequency divider 300 according to an embodiment, and FIG. 4 shows a circuit of the frequency divider 300 of FIG. 3 according to another embodiment. More particularly, FIG. 4 shows a latch 302, 304 of divider 300.

The latches 302, 304 of divider 300 are similar to latches 102, 104, except that transistors M1, M2, M3, M4, M5, M6, and M7 are not necessarily manufactured with the FDSOI technology, and that there is no dynamic back-gate control. Latches 302 and 304 thus have no input configured to receive signal BACK_GATE_TUNING.

In the example of FIG. 4, transistors M2, M3, M4, and M5 have their substrate, or back gate according to the technology in which they are manufactured, biased to VSS, that is, to ground. In an example, this biasing may be VDD or another fixed voltage such as for example VDD/2. Transistors M1, M6, and M7 have their substrate, or back gate, biased to VDD.

Unlike the example of FIG. 2, in the example of FIG. 4, transistor M1 couples node NS to a node NVSOURCE, which is a conduction node of M1, and which is coupled to ground by a resistor Rtail, also called pulling resistor.

The frequency divider 300 of FIG. 3 further comprises a control loop formed by a differential amplifier A1, having an input coupled to ground via a resistor Rref. In the shown example, differential amplifier A1 also comprises another input coupled to the node NVSOURCE of each of latches 302, 304. An output of differential amplifier A1 is coupled to the node NVBIAS_M of latches 302 and 304. The signal VBIAS_M present on node NVBIAS_M is the signal issued by amplifier A1. Node NVBIAS_M is coupled to the control node of transistor M1 by resistor R1. The control loop further comprises a node NIBIAS of application of reference current IDAC. In an example, reference current IDAC is generated by a digital-to-analog converter (DAC). In the shown example, the control loop further comprises a transistor P1, for example of PMOS type, coupling node NIBIAS and the terminal of application of voltage VDD. A control gate of transistor P1 is coupled in a current mirror to node NIBIAS. Node NIBIAS is coupled to node NVBIAS_P. The signal on node NVBIAS_P is thus linked to current IDAC.

In an example, an optional RC-type filter couples node NIBIAS to node NVBIAS_P. This filter comprises, for example, a resistor R4 coupling node NIBIAS and node NVBIAS_P, and a capacitive element C2 coupling node NVBIAS_P to the terminal of application of voltage VDD.

In an example, the control loop comprises two transistors P2 and P3, for example of PMOS type, copying reference current IDAC and coupled to amplifier A1. Each of transistors, P2, P3, couples the terminal of application of voltage VDD and amplifier A1. The control nodes of transistors P2, P3 are coupled to each other and to the node NVBIAS_P of each latch 302, 304. Thus, the current in the transistors M2 and M3 of the latch is linked to the current in P1. The role of transistors P2 and P3 is to set the currents in latches 302, 304 by controlling the voltage across resistor Rref with the voltage across resistor Rtail, so that Rtail*Itail is equal to Rref*Iref. The current in P3 is set and also flows through resistor Rref. The current in transistor P2 can be found through the resistor Rtail associated with the current of the two latches. In an example, Itail is in the order of one mA, Iref is in the order of one uA, and Rtail<<Rref. Iref being the current through resistor Rref and Itail the current through resistor Rtail.

In operation, the drain-source resistance of transistors M2, M3 is modulated as a function of current IDAC. When current IDAC increases, the current in P1, P2, and P3 increases. This results in an increase in the current in M2 and M3, as well as a decrease in the drain-source resistance Rds of these transistors M2 and M3, and an increase in the current Iref through resistor Rref. The control loop enables to control the control voltage on the gate of transistor M1 so that it remains saturated. This enables to maintain the correct operation of the divider, that is, for the division to be correctly performed, according to the operating parameters. The control loop thus controls the current Itail through pulling resistor Rtail (also called foot current) so that Rtail*Itail is equal to Rref*Iref. The current in transistors M4 and M5 remains fixed and independent of current IDAC, which sets the voltages of outputs Q_M, Q_P, regardless of the control current IDAC, and accelerate the operation of the latches in terms of frequency. The current through each latch (DC current) is not or only slightly affected by the amplitude of the radio frequency signal (input signal voltage swing). Current IDAC enables to select the appropriate amplitude in relation to the input radio frequency signal of the divider.

The examples of FIGS. 3 and 4 result in a power consumption divided by two as compared with the examples of FIGS. 1 and 2, or as compared with latch-based dividers implemented in CML (Current Mode Logic) technology, at least for frequencies in the range from 12 GHz to 35 GHz. The amplitude and frequency tuning capability is also increased, and the obtained jitter is low, for example in the order of a few tens of femtoseconds.

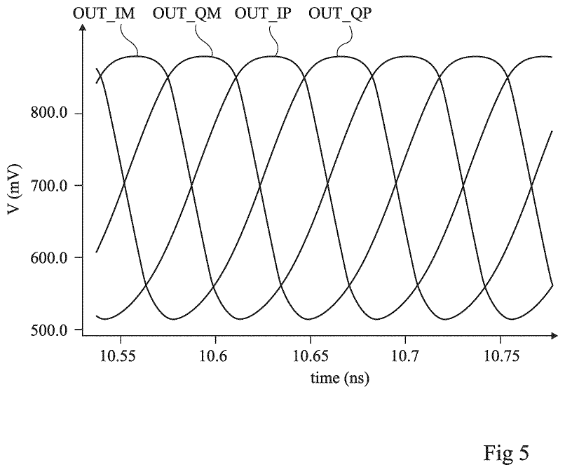

FIG. 5 shows a timing diagram of the operation of the frequency divider 300 of FIG. 3.

More particularly, FIG. 5 shows signals OUT_IM and OUT_IP present on the outputs Q_P and Q_M of latch 302, and signals OUT_QM and OUT_QP on the outputs Q_P and Q_M of latch 304. Signals OUT_QP, OUT_QM are phase-shifted by 180° from each other, and at the output of latch 302, signals OUT_IP and OUT_IP are phase-shifted by 180° from each other. Signal OUT_IP is, further, in quadrature with signal OUT_QP. Similarly, signal OUT_IM is in quadrature with signal OUT_QM.

The frequency divider described in the shown examples can be used in applications involving, for example, chains for receiving or transmitting radio frequency signals between, for example, 10 and 100 GHz. On the other hand, the frequency divider may be used in receivers for positioning devices such as GPS (Global Positioning System), Galileo etc. The described frequency divider can be integrated into 5G or 6G communication systems, particularly in receiver or transmitter chains or for data transmission. Devices requiring signals in quadrature and seeking a lower power consumption can also use the described divider.

Various embodiments and variants have been described. Those skilled in the art will understand that certain features of these various embodiments and variants may be combined, and other variants will occur to those skilled in the art. In particular, the transistors described as NMOS becoming PMOS and vice versa. In this case, those skilled in the art will modify the connections to the first and second terminals accordingly, as well as the associated substrate or back-gate voltages.

Finally, the practical implementation of the described embodiments and variants is within the abilities of those skilled in the art based on the functional indications given hereabove. In particular, with regard to amplifier A1, those skilled in the art will be able to implement it according to their knowledge, by taking into account, for example, the power supply by the current mirror(s) originating from transistors P2 and/or P3, the inputs coupled to Rtail and Rref respectively, and the output proportional to the difference of the two inputs coupled respectively to Rtail and Rref.

1. A frequency divider, comprising:
at least two latches, wherein a pulling current of each latch is configured to be controlled by a reference current.

2. The frequency divider according to claim 1, wherein the latches are in series and each latch comprises:
first and second nodes, a first clock signal application node coupled to the first node of one of the latches and to the second node of the other latch, and a second clock signal application node coupled to the second node of the one of the latches and to the first node of the other latch; and
a first pulling transistor, having a control node coupled to the first node.

3. The frequency divider according to claim 2, further comprising a control loop comprising a node of application of the reference current coupled to the second node.

4. The frequency divider according to claim 3, wherein the control loop comprises a differential amplifier comprising:
a first input coupled to a first terminal of application of a first reference voltage via a first resistor;
a second input coupled to a first conduction node of the first pulling transistor of each latch, the first conduction node of the first pulling transistor being coupled to the first terminal via a pulling resistor; and
an output coupled to the control node of the first pulling transistor.

5. The frequency divider according to claim 4, wherein the output of the differential amplifier is coupled to the control node of the first pulling transistor via a second resistor.

6. The frequency divider according to claim 4, wherein the control loop comprises at least one current mirror coupled to the differential amplifier.

7. The frequency divider according to claim 2, wherein each latch comprises:
a first branch having second and third transistors in series between a second terminal of application of a reference voltage and a second conduction node of the first pulling transistor; and
a second branch having fourth and fifth transistors in series between the second terminal and the second node;
wherein a control node of the second transistor is coupled to a junction point of the fourth and fifth transistors, and a control node of the fourth transistor is coupled to a junction point of the second and third transistors.

8. The frequency divider according to claim 7, wherein each latch comprises:
a sixth transistor coupling the second terminal and the junction point of the second and third transistors; and
a seventh transistor coupling the second terminal and the junction point of the fourth and fifth transistors;
wherein the second node is coupled to control nodes of the sixth and seventh transistors.

9. The frequency divider according to claim 3, wherein the node of application of the reference current is coupled to the second node of each latch via a third resistor.

10. The frequency divider according to claim 7, wherein:
a control node of the third transistor of a first latch of the frequency divider is coupled to the junction point of the fourth and fifth transistors of a second latch of the frequency divider; and
a control node of the fifth transistor of the first latch is coupled to the junction point of the second and third transistors of the second latch.

11. A method of operating a frequency divider comprising at least two latches, the method comprising:
controlling a pulling current of each latch by a reference current.

12. The method according to claim 11, wherein the latches are in series and each latch comprises:
a first node, common to the two latches, of application of a first clock signal;
a second node, common to the two latches, of application of a second clock signal different from the first clock signal; and
a first pulling transistor, having a control node coupled to the first node.

13. The method according to claim 12, wherein the frequency divider comprises a control loop comprising a node of application of the reference current coupled to the second node.

14. The method according to claim 13, wherein the control loop comprises a differential amplifier having:
a first input coupled to a first terminal of application of a first reference voltage via a first resistor;
a second input coupled to a first conduction node of the first pulling transistor of each latch, the first conduction node of the first pulling transistor being coupled to the first terminal via a pulling resistor; and
an output coupled to a control node of the first pulling transistor.

15. The method according to claim 14, wherein the output of the differential amplifier is coupled to the control node of the first pulling transistor via a second resistor.

16. The method according to claim 14, further comprising, by at least one current mirror:
copying the reference current; and
powering the differential amplifier with the copied reference current.

17. The method according to claim 13, wherein the node of application of the reference current is coupled to the second node of each latch via a third resistor.

18. The method according to claim 14, wherein the first reference voltage is ground and a second reference voltage is VDD.

19. The method according to claim 11, further comprising generating the reference current by a digital-to-analog converter.

20. A radio frequency device comprising:
a receiver or transmitter chain comprising:
at least two latches, wherein a pulling current of each latch is configured to be controlled by a reference current.
